(19) United States
(12) Patent Application Publication
(10) Pub. No.: US 2003/0011043 A1
(43) Pub. Date: Jan. 16, 2003

(54) MIM capacitor structure and process for making the same

(76) Inventor: Douglas R. Roberts, Austin, TX (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 09/905,785

(22) Filed: Jul. 14, 2001

(51) Int. Cl. H01L 29/00

(52) U.S. Cl. 257/532; 438/957

(57) ABSTRACT

A semiconductor device has a thin-film transistor (26) and a MIM capacitor having a capacitor dielectric layer (18) and a dielectric oxidation barrier layer (16) over an electrode comprising copper (14). In one embodiment, the dielectric oxidation barrier layer (16) is a nitride, such as silicon nitride, and the capacitor dielectric layer (18) is a metal oxide, such as tantalum oxide. The dielectric oxidation barrier layer (16) is thin as compared to the capacitor dielectric layer (18). The presence of the dielectric oxidation barrier layer (16) prevents the oxidation of the underlying electrode comprising copper (14) during deposition of the metal oxide. The copper oxidation can form a poor interface between the electrode and metal oxide, leading to adhesion problems and high leakage. Thus, the MIM capacitor of the present invention has good adhesion between the electrode and the insulator and low leakage, rendering the device useful for RF applications.

### FIELD OF INVENTION

This invention relates, generally, to the field of semiconductor devices and more particularly to metal-insulator-metal (MIM) capacitors as used in semiconductor devices.

### BACKGROUND OF THE INVENTION

As semiconductor devices shrink, there is a desire to decrease the area occupied by features, such as capacitors. To accommodate, capacitors are being formed over transistors (e.g. at the metal level) as opposed to being formed at the transistor level nearer the bulk semiconductor substrate. One example of such a capacitor is a metal-insulator-metal (MIM) capacitor. At the metal level, polysilicon cannot be used as an electrode material because deposition of polysilicon is a high temperature process that is not compatible with back-end (post-metal) processing. Copper is replacing aluminum and aluminum alloys as the predominant material for metal interconnects in semiconductor manufacturing. Therefore, it would be advantageous to use copper as the metal of a MIM capacitor electrode to avoid having to add further materials and processing steps. However, there are problems associated with using copper in conjunction with many of the high dielectric constant materials which are desirable for use in a MIM capacitor, particularly capacitors used in RF applications which require high capacitance linearity. A highly linear capacitance is one which is constant as a function of applied voltage and frequency. Known problems with using copper as an electrode material include adverse affects caused by poor mechanical and chemical stability of the copper surface, and other interactions of the copper with the capacitor dielectric materials (e.g. copper diffusion).

Therefore, a need exists for a MIM capacitor structure which includes use of copper as a capacitor electrode in which the fabrication can be easily integrated with the rest of the semiconductor manufacturing sequence, which results in a capacitor with high linearity and high capacitance, and which alleviates many of the problems associated with having copper as one of the capacitor electrodes.

### BRIEF DESCRIPTION OF THE DRAWINGS

The present invention is illustrated by way of example and not by limitation in which like references indicate similar elements, and in which:

FIG. 1 illustrates, in cross-section, a portion of semiconductor device with a bottom electrode as can be used to form a MIM capacitor in accordance with one embodiment of the present invention.

FIG. 2 illustrates the device of FIG. 1 after deposition of layers that form remaining portions of a capacitor in accordance with one embodiment of the present invention.

FIG. 3 illustrates the device of FIG. 2 with a photoresist mask prior to etching the layers used for forming a capacitor in accordance with one embodiment of the present invention.

FIG. 4 illustrates the device of FIG. 3 after etching to form a top electrode of the capacitor and a thin-film resistor in accordance with one embodiment of the present invention.

FIG. 5 illustrates the device of FIG. 4 after depositing an interlayer dielectric over the capacitor in accordance with one embodiment of the present invention.

FIG. 6 illustrates the device of FIG. 5 after etching the interlayer dielectric layer to form via openings in accordance with one embodiment of the present invention.

FIG. 7 illustrates the device of FIG. 6 after forming contacts to the capacitor and thin-film resistor in accordance with one embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

To increase the capacitance of MIM capacitor structures, the use of metal oxide materials as the capacitor dielectric is desirable due to their high dielectric constants. Generally, such metal oxides have dielectric constants greater than approximately 20. However, when forming metal oxides over a copper electrode, the copper undesirably oxidizes creating an incompatible interface between the electrode and subsequently deposited materials. More specifically, the adhesion properties between the capacitor dielectric and the electrode are poor and the presence of the copper oxide film can undesirably increase capacitor leakage.

By forming a dielectric oxidation barrier layer between the copper electrode and the metal oxide in accordance with the present invention, a MIM capacitor with a high capacitance density and good adhesion between a metal oxide dielectric and a copper electrode is formed. In a preferred embodiment, the dielectric oxidation barrier layer is a silicon nitride layer. A tantalum oxide or hafnium oxide capacitor dielectric can then be deposited without the formation of a copper oxide layer. Consequently, the final capacitor structure can have high capacitance, low leakage, and stable interfaces. One embodiment of the invention using a dielectric oxidation barrier layer will be described in regards to the figures.

FIGS. 1-7 illustrate a portion of a semiconductor device 5 as it undergoes a series of processing steps to form a MIM capacitor in accordance with the present invention. More specifically, FIG. 1 illustrates a dielectric layer 12 formed overlying a semiconductor substrate 10. In a preferred embodiment, semiconductor substrate 10 is silicon. However, other semiconductor materials can be used such as gallium arsenide and silicon-on-insulator (SOI). Typically, substrate 10 will include a number and variety of active semiconductor devices (such as MOS and/or bipolar transistors). However, for purposes of understanding the present invention, an understanding of these devices is not necessary and thus these devices are not illustrated.

To form the structure of FIG. 1, the dielectric layer 12 is patterned and etched to form an opening, sometimes referred to as a trench. A first (bottom) electrode 14 is formed over the dielectric layer 12 and within the opening, preferably by depositing the electrode material and planarizing it (e.g. by chemical mechanical polishing or etch-back). In a preferred embodiment the bottom electrode 14 comprises copper. For example, the bottom electrode 14 can be copper or an aluminum copper alloy. In one embodiment, the bottom electrode 14 is predominately copper. The bottom electrode material can be deposited using physical vapor deposition (PVD), chemical vapor deposition (CVD), electroplating combinations of these, and the like. Furthermore, the bottom electrode may actually be formed of multiple materials. For instance in copper inlaid metallization schemes, the trench is often lined with a diffusion barrier comprising tantalum or tantalum nitride. If the bottom electrode 14 is polished, it may be slotted to help control dishing of the copper during polishing. Capacitor area is generally rather larger, and large areas of copper are susceptible to dishing during polishing. Slotting the material in this case is known to alleviate the problem.

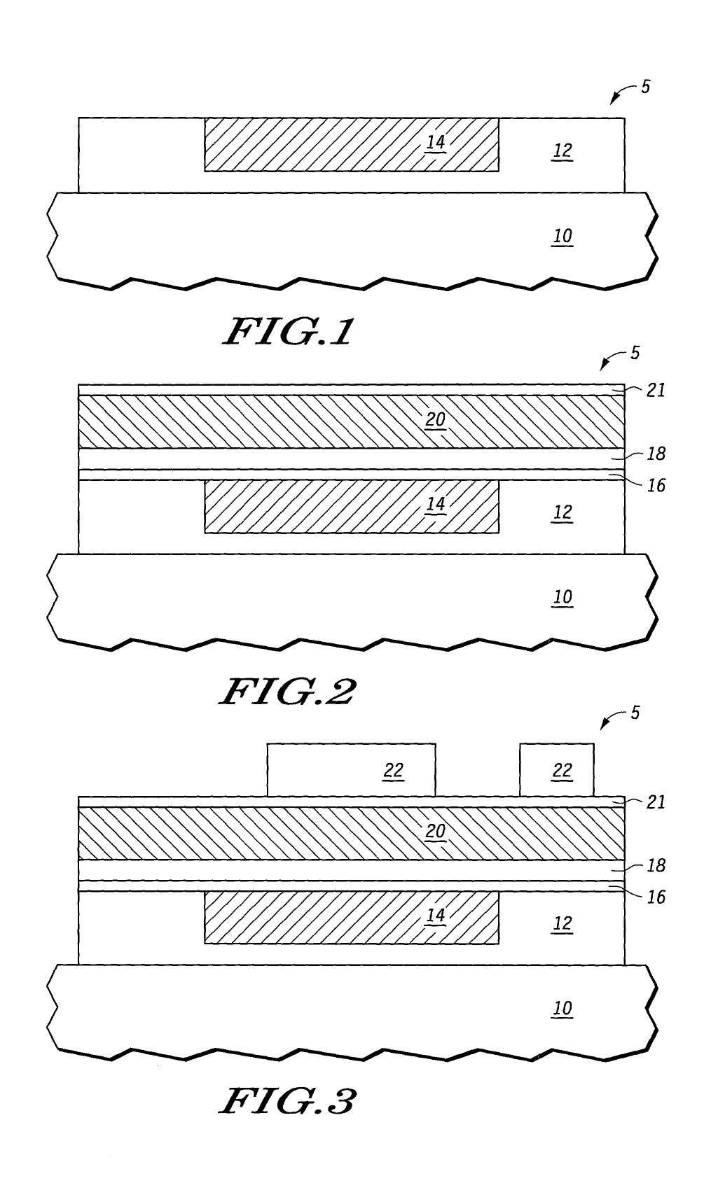

After forming the bottom electrode 14, a dielectric oxidation barrier layer 16, a capacitor dielectric layer 18, a metal layer 20 and an etch stop layer (ESL) 21 are respectively deposited over semiconductor substrate 10, as shown in FIG. 2. The dielectric oxidation barrier layer 16 is formed directly on the bottom electrode 14 by PVD, CVD, combinations of the above, and the like. However, in a preferred embodiment, the dielectric oxidation barrier layer 16 is formed by CVD or atomic layer deposition (ALD) in order to form a sufficiently thin and conformal film. A very thin film is preferred to enable the completed structure to have a sufficiently high capacitance density (see the capacitance equation below in which the thickness of layer 16 is represented as T16). In addition to being thick, it is preferred that oxidation barrier layer 16 be very conformal (e.g. not varying in thickness by more than a few 10s of nanometers over the underlying electrode). A conformal layer not only helps achieve the target capacitance, but also prevents nano-scale oxidation of the underlying copper electrode and nano-scale diffusion of copper atoms into subsequently deposited dielectric materials, either of which would degrade capacitor leakage if it occurred. As an example, the dielectric oxidation barrier layer 16 may be between approximately 1 to 10 nanometers or, more specifically, 1 to 5 nanometers. To achieve a thin and conformal dielectric oxidation barrier layer 16, a smooth top surface of bottom electrode 14 is desirable. Adding additional polishing steps or modifying the chemical mechanical polishing of the bottom electrode 14 to be more chemical than mechanical decreases the roughness of the surface. In general, the rougher the surface of the bottom electrode 14, the thicker the dielectric oxidation barrier layer 16 needs to be in order to have a conformal layer. In one embodiment, the dielectric oxidation barrier layer 16 comprises a nitride material, such as aluminum nitride or silicon nitride. In a preferred embodiment, it is silicon nitride deposited by plasma-enhanced CVD, which is sometimes referred to as PEN (plasma-enhanced nitride).

The capacitor dielectric layer 18 is formed on the dielectric oxidation barrier layer 16. Any method used to deposit the dielectric oxidation barrier layer 16 can also be used to form the capacitor dielectric layer 18. It is not necessary that the same process be used to form the two layers. However, it could be advantageous to improve processing control and throughput within a large-volume manufacturing environment. For RF applications, the capacitor dielectric layer 18 preferably comprises a metal oxide which has high linearity (e.g. a normalized capacitance variation of typically less than 100 parts per million units of voltage), such as tantalum oxide and hafnium oxide. However, for general applications in which linearity may be less critical other metal oxides such as zirconium oxide, barium strontium titanate (BST), and strontium titanate (STO) may be suitable. Furthermore, in preferred embodiments of the invention, the series capacitance formulae:

C=8.85*K16*K18/[(T18*K16)+(T16*K18)]

shows that the capacitor dielectric layer 18 is ideally thicker than the dielectric oxidation barrier layer 16 since it will have a higher dielectric constant than the barrier layer. Within this formulae, the thickness (T18) of the capacitor dielectric layer 18 is governed by its dielectric constant (K18), the dielectric constant (K16) and thickness (T16) of the dielectric oxidation barrier layer 16, and the desired capacitance density (C) for the MIM capacitor being formed. Generally, a capacitance density of 4-5 femtofarads per micron squared, or greater, is desired for RF applications. For example, if the targeted capacitance density is 4 femtofarads per square micron and the dielectric oxidation barrier layer 16 is approximately 5 nanometers of PEN (which has a dielectric constant of approximately 7) the corresponding thickness of tantalum oxide (which has a dielectric constant of about 23) is approximately 33 nanometers.

The metal layer 20 is formed over the capacitor dielectric layer (18) preferably using PVD, but other techniques including CVD, ALD, or combinations thereof could be used. The metal layer 20 will form the second (top) electrode of the capacitor and thus can be formed of any conductive material such as tantalum nitride, titanium nitride, ruthenium oxide, iridium oxide, copper, aluminum, combinations of the above, and the like. In one embodiment, the metal layer 20 comprises nitrogen and either tantalum or titanium (in the form of titanium nitride or tantalum nitride). If the metal layer 20 is copper, it may be desirable to form a dielectric layer similar to the dielectric oxidation barrier layer 16 between the metal layer 20 and the capacitor dielectric layer 18. However, there may not be an adhesion problem since the copper electrode is formed after depositing the metal oxide and thus, the copper electrode is not exposed to an oxidizing environment.

The ESL layer 21 is also deposited using PVD, CVD, ALD, or combinations thereof. As will become apparent below, the ESL layer 21 serves as an etch stop layer when etching a later deposited ILD. ESL layer 21 can also serve as a hard mask for etching metal layer 20. Furthermore, ESL layer 21 can serve as an antireflective coating (ARC) to improve optical properties during subsequent photolithography processes. In a preferred embodiment, the ESL layer 21 is silicon nitride or aluminum nitride, or alternatively tantalum oxide or hafnium oxide. Further detail of the use of ESL layer 21 is found in reference to FIG. 6 below.

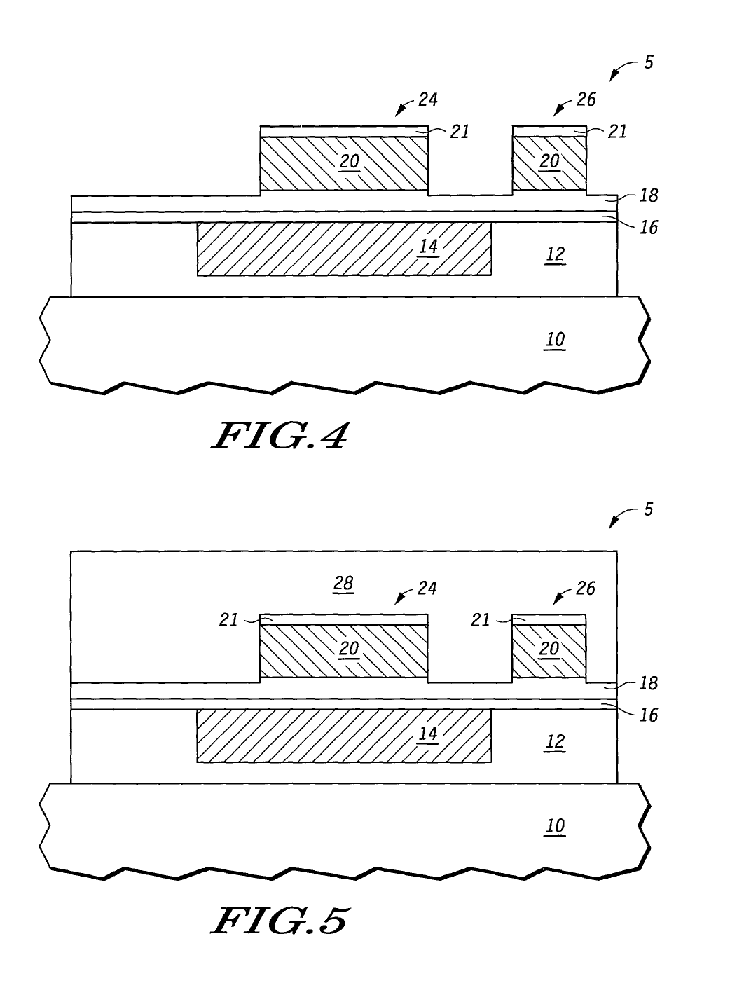

Turning to FIG. 3, a first photoresist layer 22 is deposited and patterned in order to etch the ESL layer 21 and the metal layer 20. After etching the ESL layer 21 and the metal layer 20, a top electrode 24 (or second electrode 24) and a thin-film resistor 26 are formed, as shown in FIG. 4. The resistance of resistor structure 26 is given by the usual resistance formulae:

R=(R20*L26)/(T20*W26).

The resistance (R) of resistor 26 is governed by the resistivity (R20) and thickness (T20) of layer 20, as well as the patterned linewidth (W26) and the length (L26—dimension into figure) between subsequently formed via contacts. In a preferred embodiment using tantalum nitride as layer 20, the resistivity is approximately 200 micro-ohm per centimeter as accomodates a desired range of resistance values for RF applications. Both the resistor and the capacitor top electrude structures include portions of the metal layer 20 and the ESL layer 21. The thin-film resistor 26 is formed over a portion of the capacitor dielectric layer 18. During the metal etch process, the capacitor dielectric layer 18 is over-etched in order to guarantee that the metal layer 20 is completely etched. This over-etch can be tailored to decrease the capacitor dielectric layer 18 to a desired thickness outside or beyond the capacitor and resistor areas, if desired. Since the capacitor dielectric layer 18 will not be completely removed in areas that are not part of the MIM capacitor or the thin-film resistor 26, the dielectric constant of the metal oxide can undesirably increase the capacitance in areas outside these structures. Ideally, the etch would completely remove the capacitor dielectric layer 18. However, doing so in regards to the embodiment shown in the figures could damage critical portions of the capacitor dielectric layer 18, the oxidation barrier layer 16 and/or the surface of the bottom electrode 14.

Turning to FIG. 5, an interlayer dielectric (ILD) 28 is deposited over the semiconductor substrate 10. A second photoresist layer 27 is deposited and patterned in order to etch the ILD layer 28 to form via openings 29 as shown in FIG. 6. A first chemistry is used to etch the via openings stopping on and exposing portions of the ESL layer 21 (where present) and the capacitor dielectric layer 18, which can both serve as intermediate etch stop layers. Since the thickness of the portion of the ILD that needs to be etched to form the via opening 29 over the top electrode 24 and the thin-film resistor 26 is substantially less than the thickness of the portion of the ILD to be etched to form the via opening 29 for the bottom electrode 14, at least in the instance where the ILD layer 28 had been planarized as shown in FIG. 6, the ESL layer 21 should not be completely etched using the first chemistry. This enables the etch process to continue after etching the via openings 29 above the top electrode 24 and the thin-film resistor 26 in order to form the deeper via opening for the bottom electrode 14. Thus, the first chemistry needs to be selective to the ESL layer material and perhaps even the capacitor dielectric layer 18.

Next, the etch chemistry is switched to a second chemistry for etching the exposed portions of the capacitor dielectric layer 18, the dielectric oxidation barrier layer 16, and the ESL layer 21 to completely form the via openings 29 and expose underlying conductive portions. Although the process uses two different etch chemistries, the etching of the via openings 29 can occur in the same tool and even the same chamber for improved throughput and manufacturing efficiency.

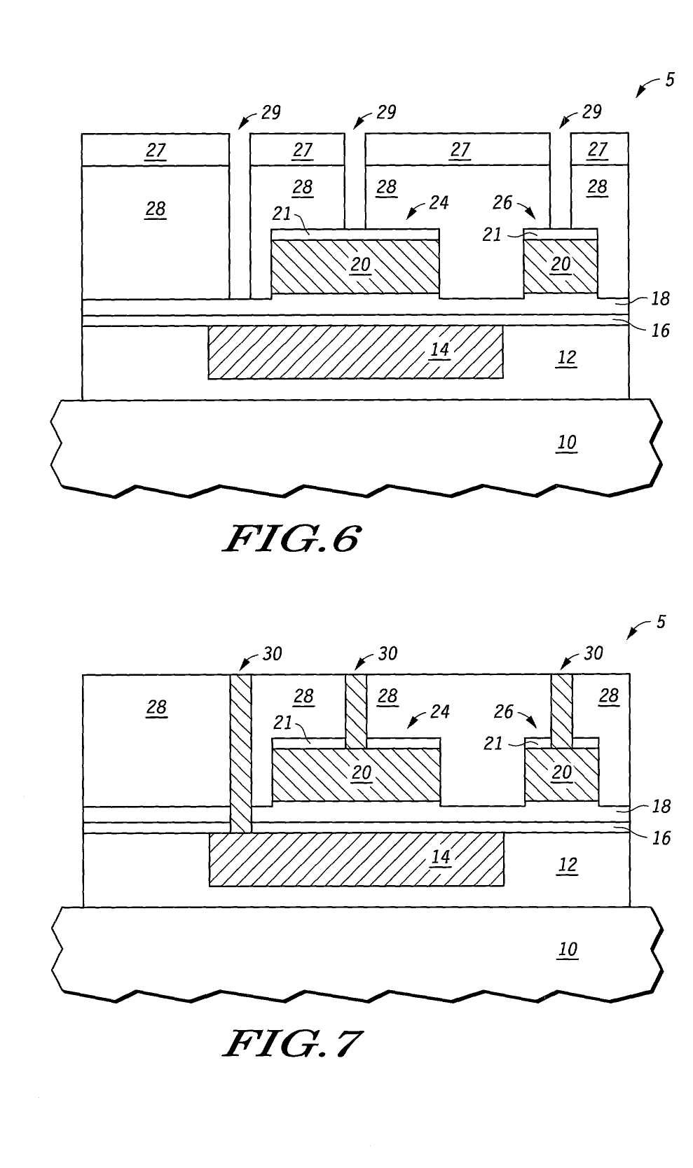

Next a conductive material is formed within via openings 29 in order to form conductive vias 30 as shown in FIG. 7. A conductor is formed in the via opening to form contacts to the top electrode 24, bottom electrode 14, and thin-film resistor 26. In a preferred embodiment, copper is electroplated and chemically mechanically polished back to form conductive vias 30.

The resulting MIM capacitor shown in FIG. 6 has the advantage of a higher capacitance than previously proposed structures because it uses metal oxide materials for the primary capacitor dielectric without the disadvantage of a poor interface between the metal oxide and the copper electrode. Due to a compatible interface, a structure in accordance with the present invention has improved leakage characteristics. In addition, the MIM structure has a high linearity because the invention enables use of a metal oxide capacitor dielectric and a dielectric oxidation barrier layer which themselves have high linearity. Such on-chip capacitors are widely useful for demanding high-frequency (>1 Ghz) RF circuits, for mixed-signal analog and filtering.

The embodiment described as shown in the figures is a MIM capacitor wherein the top electrode 24 is smaller in size compared to the bottom electrode 14. In another embodiment, the top electrode 24 can be oversized as compared to the bottom electrode 14. In this embodiment, the contact for the bottom electrode 14 is formed prior to the formation of the bottom electrode 14 because the contact, instead of being formed over the bottom electrode, is underneath the bottom electrode 14. In addition, in this embodiment it may be possible to completely remove the capacitor dielectric layer 18 without damaging critical portions of the capacitor structure when etching ESL layer 21 and metal layer 20. By doing so the disadvantage of having a high dielectric constant material underneath ILD layer 28 is overcome. However, it remains possible that when removing the capacitor dielectric layer 18 from areas outside the MIM capacitor and not underneath the thin-film resistor, that other structures underneath the layers, such as an adjacent copper pad structure, may be damaged. Such related structures are not explicity shown in the figures, but are generally always present on-chip as an essential part of the IC interconnect circuitry.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

In the foregoing specification, the invention has been described with reference to specific embodiments. However, one of ordinary skill in the art appreciates that various modifications and changes can be made without departing from the scope of the present invention as set forth in the claims below. For example, as described and illustrated, the MIM capacitor is formed in a single damascene manner within the device. However, one of ordinary skill would recognize that a similar structure could be incorporated into a dual damascene integration. Accordingly, the specification and figures are to be regarded in an illustrative rather than a restrictive sense, and all such modifications are intended to be included within the scope of present invention.

What is claimed:

1. A metal-insulator-metal (MIM) capacitor structure in a semiconductor device comprising:
a semiconductor substrate;
a dielectric layer overlying the semiconductor substrate;
a first capacitor electrode formed over the dielectric layer, wherein the first capacitor electrode comprises copper;
a dielectric oxidation barrier layer formed on the first capacitor electrode;
a capacitor dielectric layer formed on the dielectric oxidation barrier layer, wherein the capacitor dielectric layer comprises a metal oxide; and
a second capacitor electrode formed over the capacitor dielectric layer, wherein the second capacitor electrode comprises a metal.

2. The metal-insulator-metal (MIM) capacitor structure of claim 1 wherein the dielectric oxidation barrier layer comprises silicon nitride.

3. The metal-insulator-metal (MIM) capacitor structure of claim 2 wherein the dielectric oxidation barrier layer has a thickness between approximately 1-10 nanometers.

4. The metal-insulator-metal (MIM) capacitor structure of claim 1 wherein the dielectric oxidation barrier layer comprises aluminum nitride.

5. The metal-insulator-metal (MIM) capacitor structure of claim 1 wherein the capacitor dielectric layer comprises tantalum oxide.

6. The metal-insulator-metal (MIM) capacitor structure of claim 1 wherein the capacitor dielectric layer comprises hafnium oxide.

7. The metal-insulator-metal (MIM) capacitor structure of claim 1 further comprising a thin-film resistor comprised of the metal and formed over a portion of the capacitor dielectric layer.

8. The metal-insulator-metal (MIM) capacitor structure of claim 7 wherein the metal comprises nitrogen and either tantalum or titanium.

9. A process for forming a metal-insulator-metal (MIM) capacitor structure comprising:
providing a semiconductor substrate;
forming a dielectric layer over the semiconductor substrate;
forming a first capacitor electrode over the dielectric layer, wherein the first capacitor electrode comprises copper;
forming a dielectric oxidation barrier layer on the first capacitor electrode;
forming a capacitor dielectric layer on the dielectric oxidation barrier layer, wherein the capacitor dielectric layer comprises a metal oxide; and
forming a second capacitor electrode formed over the capacitor dielectric layer, wherein the second capacitor electrode comprises a metal.

10. The process of claim 9 wherein:
the first capacitor electrode is comprised predominately of copper; and
the dielectric oxidation barrier layer is a nitride.

11. The process of claim 10 wherein:
the dielectric oxidation barrier layer comprises silicon nitride and has a thickness of between approximately 1-10 nanometers.

12. The process of claim 11 wherein:
the capacitor dielectric layer comprises a metal oxide selected from a group consisting of tantalum oxide and hafnium oxide.

13. A process for forming a metal-insulator-metal (MIM) capacitor structure comprising:
providing a semiconductor substrate;
forming a dielectric layer over the semiconductor substrate;
patterning an opening in the dielectric layer;
depositing a layer comprising copper over the dielectric layer and in the opening;
polishing the layer comprising copper to form a first capacitor electrode;
depositing a dielectric oxidation barrier layer on the first capacitor electrode;
depositing a capacitor dielectric layer on the dielectric oxidation barrier layer, wherein the capacitor dielectric layer comprises a metal oxide;
depositing a metal layer over the capacitor dielectric layer; and
patterning the metal layer to form a second capacitor electrode.

14. The process of claim 13 wherein:
depositing a dielectric oxidation barrier layer comprises depositing either a silicon nitride layer or an aluminum nitride layer.

15. The process of claim 14 wherein:
depositing a dielectric oxidation barrier layer comprises depositing a dielectric oxidation barrier layer by atomic layer deposition.

16. The process of claim 15 wherein:
depositing a dielectric oxidation barrier layer comprises depositing a dielectric oxidation barrier layer by chemical vapor deposition.

17. The process of claim 13 wherein:
the dielectric oxidation barrier layer is deposited to a thickness of between approximately 1-10 nanometers.

18. The process of claim 13 further comprising:
forming an etch stop layer over the metal layer prior to patterning;
depositing an interlayer dielectric over the second capacitor electrode;
etching the interlayer dielectric to form a first via opening which exposes a portion of the etch stop layer over the second capacitor electrode;
etching the portion of the etch stop layer which is exposed; and
depositing a conductor into the first via opening to form a contact to the second capacitor electrode.

19. The process of claim 18 wherein:
etching the interlayer dielectric also forms a second via opening which exposes a portion of the capacitor dielectric layer over the first capacitor electrode;
etching the portion of the etch stop layer also etches the portion of the capacitor dielectric layer which is exposed; and
depositing a conductor includes depositing a conductor into the second via opening to form a contact to the first capacitor electrode.

20. The process of claim 13 wherein:
patterning the metal layer includes etching the metal layer and as a result of etching the metal layer at least a portion of the capacitor dielectric layer is removed.

21. The process of claim 13 wherein:
patterning comprises patterning the metal layer to form a second capacitor electrode and simultaneously forming a thin-film resistor.

22. The process of claim 21 wherein:
depositing a metal layer comprises depositing a metal layer comprising nitrogen and either tantalum or titanium.
